(19) United States
(12) Patent Application Publication
(10) Pub. No.: US 2026/0086159 A1
(43) Pub. Date: Mar. 26, 2026

(54) Battery Management Apparatus and Operating Method Thereof

(71) Applicant: LG Energy Solution, Ltd., Seoul (KR)

(72) Inventor: Sung Won Kim, Daejeon (KR)

(73) Assignee: LG Energy Solution, Ltd., Seoul (KR)

(21) Appl. No.: 19/112,414

(22) PCT Filed: Sep. 1, 2023
(86) PCT No.: PCT/KR2023/013096

§ 371 Date: Mar. 17, 2025

(30) Foreign Application Priority Data
Oct. 19, 2022 (KR) 10-2022-0135174

(51) Int. Cl. G01R 31/3835; G01R 31/389

(52) U.S. Cl. CPC G01R 31/3835; G01R 31/389

(57) ABSTRACT

A battery management apparatus includes at least one capacitor respectively connected to at least one battery and a controller configured to apply current to the at least one capacitors to pre-charge the at least one capacitors, measure a voltage of each of the at least one capacitors, and control impedance measurement of the at least one batteries based on whether the voltage of the at least one capacitors is within a threshold range.

### CROSS-REFERENCE TO RELATED APPLICATIONS

The present application is a national phase entry under 35 U.S.C. § 371 of International Application No. PCT/KR2023/013096, filed on Sep. 1, 2023, and published as International Publication No. WO 2024/085426 A1, which claims priority from Korean Patent Application No. 10-2022-0135174, filed on Oct. 19, 2022, all of which are hereby incorporated herein by reference in their entireties.

### TECHNICAL FIELD

Embodiments disclosed herein relate to a battery management apparatus and an operating method thereof.

### BACKGROUND

Recently, research and development of secondary batteries have been actively performed. Secondary batteries, which are chargeable/dischargeable batteries, may include all of conventional nickel (Ni)/cadmium (Cd) batteries, Ni/metal hydride (MH) batteries, etc., and recent lithium-ion batteries. Among the secondary batteries, a lithium-ion battery has a much higher energy density than those of conventional Ni/Cd batteries, Ni/MH batteries, etc. Moreover, the lithium-ion battery may be manufactured to be small and lightweight, such that the lithium-ion battery has been used as a power source of mobile devices, and recently, a use range thereof has been extended to power sources for electric vehicles, attracting attention as next-generation energy storage media.

To measure an impedance of the lithium ion battery, electrochemical impedance spectroscopy may be used. The electrochemical impedance spectroscopy may accurately calculate impedance which is a factor hindering electricity transmission when a chemical reaction occurs at an electrode of the battery. In a way to measure the impedance, after a precise shunt resistor is serially connected to a battery, alternating current is generated to measure voltage across opposite ends of the resistor and voltage across opposite ends of the battery to measure the impedance of the battery. When the voltage across the opposite ends of the battery is measured, + side and − side are clamped by a DC voltage and then a pre-charging capacitor is connected to measure the voltage. However, a conventional electrochemical impedance spectroscopy measures the impedance based on whether a specific time has elapsed, without monitoring a voltage of pre-charging capacities connected to the battery, thereby degrading the accuracy of the impedance.

### SUMMARY OF THE INVENTION

### Technical Problem

Embodiments disclosed herein aim to provide a battery management apparatus and an operating method thereof, in which by monitoring a voltage of capacitors connected to a battery, the accuracy of an impedance of the battery measured by electrochemical impedance spectroscopy may be improved.

Technical problems of the embodiments disclosed herein are not limited to the above-described technical problems, and other unmentioned technical problems would be clearly understood by one of ordinary skill in the art from the following description.

### Technical Solution

A battery management apparatus according to an embodiment disclosed herein includes one or more capacitors, each capacitor of the one or more capacitors connected to a respective battery among one or more batteries and a controller configured to apply current to each of the one or more capacitors to pre-charge the one or more capacitors, measure a respective voltage of each of the one or more capacitors, and, for each battery of the one or more batteries, control an impedance measurement of the battery based on whether the voltage of the capacitor connected to the battery is within a threshold range.

In an embodiment, the battery management apparatus may further include a sensor configured to measure impedance of the battery, and the controller may be further configured to, in response to each capacitor being within the threshold range, generate a control signal for measuring the impedance of the battery connected to the capacitor and transmit the control signal to the sensor.

In an embodiment, the controller may be further configured to, in response to the voltage of any capacitor being outside of the threshold range, determine whether a pre-charging time for pre-charging the capacitor is greater than or equal to a threshold time.

In an embodiment, the controller may be further configured to re-determine whether the voltage of the capacitor is within the threshold range, in response to the pre-charging time for pre-charging the capacitor being greater than or equal to the threshold time.

In an embodiment, the controller may be further configured to repeatedly determine whether the voltage of the capacitor is within the threshold range until either (i) the voltage of the capacitor is determined to be within the threshold range; or (ii) the voltage of the capacitor is determined to be outside of the threshold range a predetermined threshold number of times.

In an embodiment, the controller may be further configured to generate an abnormality signal of the battery in response to the voltage of the capacitor being determined to be outside of the threshold range the predetermined threshold number of times.

In an embodiment, the controller may be further configured to pre-charge the capacitor in response to the pre-charging time being less than the threshold time.

An operating method of a battery management apparatus according to an embodiment disclosed herein includes applying current to a capacitor connected to a battery to pre-charge the capacitor, measuring a voltage of the capacitor, and measuring an impedance of the battery based on whether the voltage of the capacitor is within a threshold range.

In an embodiment, measuring the impedance of the battery may include generating a control signal for measuring the impedance of the battery and transmitting the control signal to a sensor.

In an embodiment, measuring the impedance of the battery may include determining, in response to the voltage of the capacitor being outside of the threshold range, whether the pre-charging time for pre-charging the capacitor is greater than or equal to the threshold time.

In an embodiment, the operating method may further include re-determining whether the voltage of the capacitor is within the threshold range in response to the pre-charging time for pre-charging the capacitor being greater than or equal to a threshold time.

In an embodiment, the operating method may further include determining whether the voltage of the capacitor is within the threshold range until either (i) the voltage of the capacitor is determined to be within the threshold range; or (ii) the voltage of the capacitor is determined to be outside of the threshold range a predetermined threshold number of times.

In an embodiment, the operating method may further include generating an abnormality signal of the battery in response to the voltage of the capacitor being determined to be outside of the threshold range the predetermined threshold number of times.

In an embodiment, the operating method may further include generating a control signal for pre-charging the capacitor and transferring the control signal to the capacitor, in response to the pre-charging time being less than the threshold time.

### Advantageous Effects

A battery management apparatus and an operating method thereof according to an embodiment disclosed herein may improve the accuracy of an impedance of a battery measured by electrochemical impedance spectroscopy by monitoring a voltage of capacitors connected to the battery.

Moreover, the battery management system and the operating method thereof according to an embodiment disclosed herein may stably manage the lifespan of a battery.

### BRIEF DESCRIPTION OF THE DRAWINGS

FIG. 1 is a diagram conceptually showing a battery swapping station according to an embodiment disclosed herein.

FIG. 2 is a diagram conceptually showing a battery swapping station according to another embodiment disclosed herein.

FIG. 3 is a block diagram of a battery management apparatus according to an embodiment disclosed herein.

FIG. 4 is a block diagram conceptually showing a battery management pack according to an embodiment disclosed herein.

FIG. 5 is a flowchart of an operating method of a battery management apparatus according to an embodiment disclosed herein.

FIG. 6 is a flowchart showing an operating method of a battery management apparatus, according to another embodiment disclosed herein.

FIG. 7 is a block diagram showing a hardware configuration of a computing system for performing an operating method of a battery management apparatus, according to an embodiment disclosed herein.

### DETAILED DESCRIPTION

Hereinafter, embodiments disclosed in this document will be described in detail with reference to the exemplary drawings. In adding reference numerals to components of each drawing, it should be noted that the same components are given the same reference numerals even though they are indicated in different drawings. In addition, in describing the embodiments disclosed in this document, when it is determined that a detailed description of a related known configuration or function interferes with the understanding of an embodiment disclosed in this document, the detailed description thereof will be omitted.

To describe a component of an embodiment disclosed herein, terms such as first, second, A, B, (a), (b), etc., may be used. These terms are used merely for distinguishing one component from another component and do not limit the component to the essence, sequence, order, etc., of the component. The terms used herein, including technical and scientific terms, have the same meanings as terms that are generally understood by those skilled in the art, as long as the terms are not differently defined. Generally, the terms defined in a generally used dictionary should be interpreted as having the same meanings as the contextual meanings of the relevant technology and should not be interpreted as having ideal or exaggerated meanings unless they are clearly defined in the present application.

FIG. 1 is a diagram conceptually showing a battery swapping station according to an embodiment disclosed herein.

Referring to FIG. 1, a battery swapping system (BSS) 1000 may provide an overall management service for evaluation, measurement, charge, exchange, etc., of a battery, and in the present disclosure, a function of the battery swapping system 1000 will be described based on a battery swapping service. Herein, the battery swapping service may mean a service that analyzes states of a plurality of batteries 10, 20, 30, and 40 that are service subjects and swaps the batteries 10, 20, 30, 40, and 50 with other batteries 10, 20, 30, and 40 according to an analysis result. Such swapping may be automatically performed by a manager and/or user's setting. For example, the battery swapping station 1000 may provide a user with a battery swapping service by collecting the batteries 10, 20, 30, and 40 returned from the user and providing other previously charged batteries 10, 20, 30, and 40 to the user.

Herein, the batteries 10, 20, 30, and 40 may be devices mounted on a subject device (e.g., an electrical transportation such as an electrical vehicle, an electrical scooter, an electrical bike, etc.) to supply power for driving the subject device, and may be implemented in the form of battery packs. The battery pack may include a battery that stores power and a battery management system (BMS) that controls an operation of the battery. The battery may include at least one battery cell for storing power under control of the BMS. The battery cell, which is a basic unit of a battery available by charging and discharging electrical energy, may be a lithium ion (Li-ion) battery, an Li-ion polymer battery, a nickel-cadmium (Ni—Cd) battery, a nickel hydrogen (Ni-MH) battery, etc., and is not limited thereto. The BMS may control charge and discharge of the battery, and collect data that is a basis for state analysis of the battery and transmit the data to an external device at the request of the external device.

Hereinbelow, a description will be made assuming that the plurality of batteries 10, 20, 30, and 40 are implemented in the form of battery packs. While it is illustrated in FIG. 1 that the number of batteries 10, 20, 30, and 40 is 4, the batteries may include n batteries (n is a natural number greater than or equal to 2).

Depending on an embodiment, the battery swapping station 1000 may be arranged in a service station where the battery swapping service is provided or in a space that is separate from the service station.

The battery swapping station 1000 may analyze the states of the plurality of batteries 10, 20, 30, and 40 connected thereto and swap the batteries 10, 20, and 30 with other batteries 10, 20, and 30 or reuse (i.e., not swap) the batteries 10, 20, and 30, according to a result of state analysis. The battery swapping station 1000 may autonomously determine whether state analysis with respect to the plurality of batteries 10, 20, 30, and 40 and/or swapping of the batteries 10, 20, and 30 are required, but according to another embodiment, at least some operation may be performed in association with a server (e.g., a cloud server) connected through a network. For example, the battery swapping station 1000 may transmit to the cloud server, information that is a basis for determining whether swapping of a battery is required, and the cloud server may transmit to the battery swapping station 1000, the information about whether swapping of the battery is required.

FIG. 2 is a diagram conceptually showing a battery swapping station according to another embodiment disclosed herein.

Referring to FIG. 2, the battery swapping station 1000 may include a battery slot portion 100, a battery management apparatus 200, and a charger 300.

The battery slot portion 100 may accommodate the plurality of batteries 10, 20, 30, and 40 connected. The battery slot portion 100 may include a plurality of battery slots that respectively accommodate the plurality of batteries connected. The battery slot portion 100 may be connected to the battery management apparatus 200. The plurality of batteries 10, 20, 30, and 40 accommodated in the battery slot portion 100 may be physically controlled based on a control signal of the battery management apparatus 200.

The battery management apparatus 200 may manage and/or control a state and/or an operation of the plurality of batteries 10, 20, 30, and 40. The battery management apparatus 200 may manage charge and/or discharge of the plurality of batteries 10, 20, 30, and 40.

In addition, the battery management apparatus 200 may monitor a voltage, a current, a temperature, etc., of each of the plurality of batteries 10, 20, 30, and 40. The battery management apparatus 200 may calculate parameters indicating the states of the plurality of batteries 10, 20, 30, and 40 based on measurement values of the monitored voltage, current, temperature, etc.

The battery management apparatus 200 may manage a state of charge (SoC) and/or a state of health (SoH) of the plurality of batteries 10, 20, 30, and 40. The battery management apparatus 200 may receive SoC information of each of the plurality of batteries 10, 20, 30, and 40 from the corresponding batteries 10, 20, and 30. Herein, the SoC information may indicate a current SoC of the corresponding battery and the SoC may mean a charge state of a battery included in the battery, i.e., a remaining capacity rate.

A battery management apparatus for the corresponding battery may calculate the remaining capacity rate by dividing the current available capacity of the battery by a total capacity of the battery. For example, the remaining capacity rate may be calculated as a percentage. According to another embodiment, the battery management apparatus 200 may obtain SoC information by directly calculating a remaining capacity rate for a battery of the battery without receiving the SoC information from the BMS for the battery.

The charger 300 may charge each of the plurality of batteries 10, 20, 30, and 40 under control of the battery management apparatus 200. The charger 300 may be supplied with power from an external utility power source to convert the power into a power form that may be received by the plurality of batteries 10, 20, 30, and 40, and supply the power to the plurality of batteries 10, 20, 30, and 40. According to an embodiment, the charger 300 may supply power until the SoCs of the plurality of batteries 10, 20, 30, and 40 reach 100%, thus fully charging the plurality of batteries 10, 20, 30, and 40.

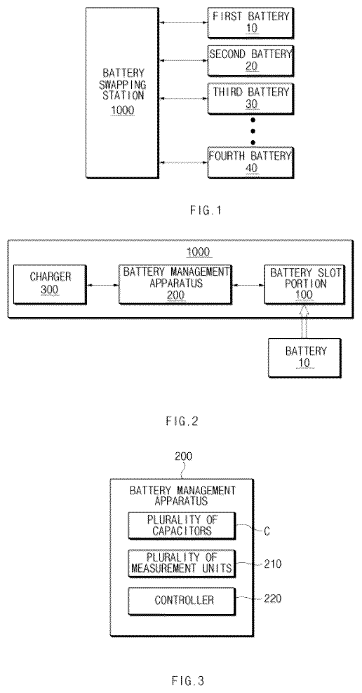

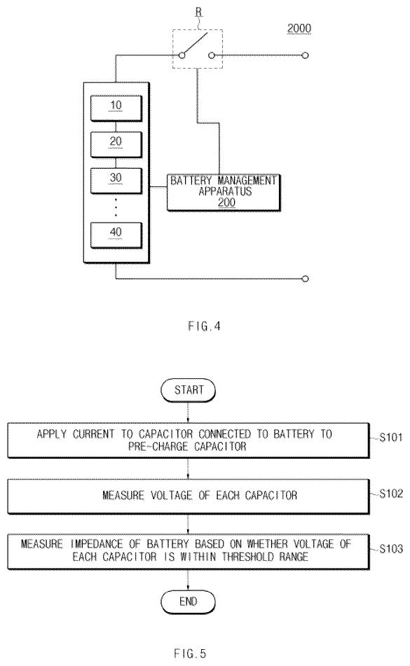

Hereinbelow, a configuration and an operation of the battery management apparatus 200 will be described in more detail with reference to FIG. 3.

FIG. 3 is a block diagram of a battery management apparatus according to an embodiment disclosed herein.

Referring to FIG. 3, the battery management apparatus 200 may a plurality of capacitors C, a plurality of measurement units 210, and a controller 230.

The battery management apparatus 200 may measure alternating current impedances of the plurality of batteries 10, 20, 30, and 40. For example, the battery management apparatus 200 may measure alternating current impedances of the plurality of batteries 10, 20, 30, and 40 by using electrochemical impedance spectroscopy. The electrochemical impedance spectroscopy may detect impedance which is a factor hindering electricity transmission when a chemical reaction occurs at electrodes of the plurality of batteries 10, 20, 30, and 40. The battery management apparatus 200 may measure alternating current impedances of the plurality of batteries 10, 20, 30, and 40 with a non-destructive testing method by using electrochemical impedance spectroscopy.

When measuring the alternating current impedances of the plurality of batteries 10, 20, 30, and 40, the battery management apparatus 200 may generate direct current voltage DC by connecting a capacitor C to the battery to prevent overcurrent generated at the early driving of the plurality of plurality of batteries 10, 20, 30, and 40, that is, inrush current. Herein, generation of the direct current voltage DC in the capacitor C by connecting the capacitor C to the battery by the battery management apparatus 200 may be defined as pre-charging, or voltage charged in the capacitor C may be defined as pre-charging voltage.

Each of a plurality of capacitors C may be electrically connected to opposite ends of at least one of the plurality of batteries 10, 20, 30, and 40. Each of the plurality of capacitors C may be charged by being supplied with current from the charger 300. A time for generating direct current voltage by supplying current to the plurality of capacitors C may be referred to as a pre-charging time.

The plurality of measurement units 210 may measure impedances of the plurality of batteries 10, 20, 30, and 40 electrically connected respectively to the plurality of capacitors C.

For example, when the battery swapping station 1000 includes 8 battery slots, the plurality of measurement units 210 may be implemented with one measurement unit 210, and the measurement unit 210 may measure impedances of 8 batteries respectively inserted into the 8 battery slots.

For example, when the battery swapping station 1000 includes 8 battery slots, the plurality of measurement units 210 may be implemented with two measurement units 210, and each of the two measurement units 210 may measure impedances of 4 batteries respectively inserted into 4 battery slots.

Each of the plurality of measurement units 210 may be electrically connected to any one of the plurality of capacitors C.

For example, when the battery swapping station 1000 includes 8 battery slots, the plurality of measurement units 210 may be implemented with one measurement unit 210, and the measurement unit 210 may be electrically connected to 8 capacitors connected to 8 batteries.

For example, when the battery swapping station 1000 includes 8 battery slots, the plurality of measurement units 210 may be implemented with two measurement units 210, and each of the two measurement units 210 may be electrically connected to 4 capacitors connected to 4 batteries.

Each of the plurality of measurement units 210 may measure impedances of the plurality of batteries 10, 20, 30, and 40 based on a control signal of the controller 220. The plurality of measurement units 210 may measure impedances of the plurality of batteries 10, 20, 30, and 40 by using electrochemical impedance spectroscopy (EIS).

The plurality of measurement units 210 may calculate alternating current impedance spectrums of the plurality of batteries 10, 20, 30, and 40 based on a change in amplitude and phase of a signal detected from the plurality of batteries 10, 20, 30, and 40 with respect to a change in frequency of alternating current (AC) power applied to the plurality of batteries 10, 20, 30, and 40.

The controller 220 may pre-charge the plurality of capacitors C by applying alternating current to the plurality of capacitors C. The controller 220 may measure a voltage of each of the plurality of capacitors C.

For example, the controller 220 may obtain a voltage of each of the plurality of capacitors C from an analog-to-digital converter (ADC) that converts a voltage of each of the plurality of capacitors C into a digital signal.

The controller 220 may determine whether the voltages of the plurality of capacitors C are within a threshold range. The controller 220 may control impedance measurement of the plurality of batteries 10, 20, 30, and 40 by the plurality of measurement units 210 based on the voltages of the plurality of capacitors C being within the threshold range. For example, the controller 220 may determine whether the voltage of each of the plurality of capacitors C is within a threshold range of 1.8 V±5%.

When the voltage of each of the plurality of capacitors C is within the threshold range, the controller 220 may generate a control signal for measuring the impedances of the plurality of batteries 10, 20, 30, and 40 and transfer the control signal to the plurality of measurement unit 210.

The controller 220 may determine whether the pre-charging time for pre-charging the plurality of capacitors C is greater than or equal to the threshold time, when the voltage of each of the plurality of capacitors C is out of the threshold range. For example, the controller 220 may determine whether the pre-charging time of the plurality of capacitors C is greater than or equal to a threshold time of 4000 ms, when the voltage of each of the plurality of capacitors C is out of a threshold range of 1.8 V±5%.

When the pre-charging time is greater than or equal to the threshold time, the controller 220 may re-determine whether the voltage of each of the plurality of capacitors C is within the threshold range after the elapse of a specific time. The controller 220 may redetermine, up to a threshold number of times, whether the voltages of the plurality of capacitors C are within the threshold range.

The controller 220 may generate abnormality signals of the plurality of batteries 10, 20, 30, and 40 when re-determining, up to the threshold number of times, whether the voltage of each capacitor C is within the threshold range. For example, the controller 220 may generate an error signal when redetermining whether the voltage of each of the plurality of capacitors C is within the threshold range three times that are the threshold number of times.

The controller 220 may continue pre-charging the plurality of capacitors C when the pre-charging time is less than the threshold time. For example, the controller 220 may continue pre-charging the capacitor C until the remaining time T_remain when the pre-charging time is less than the threshold time. herein, the remaining time T_remain will be described with reference to [Equation 1] below.

$${T}_{remain} = α ( {V}_{max} - {V}_{adc} ) * ( \frac{{T}_{adc}}{{V}_{adc} - {V}_{init}} ) \qquad [ Equation 1 ]$$

Herein, a may mean an environment variable, i.e., a feature value of the capacitor C. V_max may be a maximum charging voltage of the capacitor C, e.g., 1.8 V. V_adc may mean a voltage of each capacitor C, obtained from an analog-to-digital converter. Herein, T_adc may mean a pre-charging time for pre-charging the plurality of capacitors C. V_init may mean the voltages of the plurality of capacitors C when pre-charging starts.

The controller 220 may calculate the remaining time T_remain based on [Equation 1], and continue pre-charging the plurality of capacitors C during the remaining time T_remain.

FIG. 4 is a block diagram conceptually showing a battery pack of a vehicle battery system, according to an embodiment disclosed herein.

Referring to FIG. 4, a battery pack 2000 according to an embodiment disclosed herein may include a plurality of battery modules M1, M2, M3, and M4, the battery management apparatus 200, and a relay R.

According to an embodiment, the battery management apparatus 200 may be implemented with a battery management apparatus of a vehicle battery system.

The plurality of battery modules M1, M2, M3, and M4 of the vehicle battery system may include a plurality of battery cells. Although the plurality of battery modules M1, M2, M3, and M4 are illustrated as four in FIG. 4, the present disclosure is not limited thereto, and the plurality of battery modules M1, M2, M3, and M4 may include n battery cells (n is a natural number equal to or greater than 2).

The battery management apparatus 200 of the vehicle battery system may manage and/or control a state and/or an operation of the plurality of battery modules M1, M2, M3, and M4. For example, the battery management apparatus 200 may manage and/or control the states and/or operations of a plurality of battery cells included in the plurality of battery modules M1, M2, M3, and M4. The battery management apparatus 200 may manage charging and/or discharging of the plurality of battery modules M1, M2, M3, and M4.

The battery management apparatus 200 may monitor a voltage, a current, a temperature, etc., of each of the plurality of battery modules M1, M2, M3, and M4 and/or each of the plurality of battery cells included in the plurality of battery modules M1, M2, M3, and M4. A sensor or various measurement modules for monitoring performed by the battery management apparatus 200, which are not shown, may be additionally installed in the plurality of battery modules M1, M2, M3, and M4, a charging/discharging path, any position of the plurality of battery modules M1, M2, M3, and M4, etc.

The battery management apparatus 200 may control an operation of the relay R. For example, the battery management apparatus 200 may short-circuit the relay R to supply power to a target device. The battery management apparatus 200 may short-circuit the relay R when a charging device is connected to the battery pack 1000.

The alternating current impedances of the plurality of battery modules M1, M2, M3, and M4 may be measured. For example, the battery management apparatus 200 may measure alternating current impedances of the plurality of battery modules M1, M2, M3, and M4 by using electrochemical impedance spectroscopy.

Each of the plurality of capacitors C may be electrically connected to opposite ends of at least one of the plurality of battery modules M1, M2, M3, and M4. The plurality of measurement units 210 may measure impedances of the plurality of battery modules M1, M2, M3, and M4 electrically connected respectively to the plurality of capacitors C. Each of the plurality of measurement units 210 may be electrically connected to any one of the plurality of capacitors C. Each of the plurality of measurement units 210 may measure the impedances of the plurality of battery modules M1, M2, M3, and M4 based on the control signal of the controller 220.

The controller 220 may pre-charge the plurality of capacitors C by applying alternating current to the plurality of capacitors C. The controller 220 may measure a voltage of each of the plurality of capacitors C. For example, the controller 220 may obtain a voltage of each of the plurality of capacitors C from an analog-to-digital converter (ADC) that converts a voltage of each of the plurality of capacitors C into a digital signal.

The controller 220 may determine whether the voltages of the plurality of capacitors C are within a threshold range. The controller 220 may control impedance measurement of the plurality of battery modules M1, M2, M3, and M4 by the plurality of measurement units 210 based on the voltages of the plurality of capacitors C being within the threshold range.

According to an embodiment, the battery management apparatus 200 may be connected to outside of a battery management apparatus of an existing vehicle battery system to measure the impedances of the plurality of battery modules M1, M2, M3, and M4 through communication with the battery management apparatus of the vehicle battery system.

As described above, the battery management apparatus according to an embodiment disclosed herein may monitor voltages of capacitors connected to the battery to improve the accuracy of the impedance, measured using electrochemical impedance spectroscopy, of the battery.

FIG. 5 is a flowchart of an operating method of a battery management apparatus according to an embodiment disclosed herein.

Referring to FIG. 5, an operating method of a battery management apparatus according to an embodiment disclosed herein includes operation S101 of apply current to a plurality of capacitors connected to a plurality of batteries to pre-charge the plurality of capacitors, operation S102 of measuring voltage of each of the plurality of capacitors, and operation S103 of measuring impedances of the plurality of batteries based on whether the voltage of each of the plurality of capacitors is within a threshold range.

Hereinbelow, operations S101 through S103 will be described in detail with reference to FIGS. 1 and 4. The battery management apparatus 200 may be substantially the same as the battery management apparatus 200 described with reference to FIGS. 1 to 4, and thus will be briefly described to avoid redundant description.

In operation S101, each of a plurality of capacitors C may be electrically connected to opposite ends of at least one of the plurality of batteries 10, 20, 30, and 40.

In operation S101, the controller 220 may pre-charge the plurality of capacitors C by applying alternating current to the plurality of capacitors C.

In operation S102, the controller 220 may measure a voltage of each of the plurality of capacitors C. In operation S102, for example, the controller 220 may obtain a voltage of each of the plurality of capacitors C from an analog-to-digital converter (ADC) that converts a voltage of each of the plurality of capacitors C into a digital signal.

In operation S103, the controller 220 may determine whether the voltages of the plurality of capacitors C are within a threshold range. In operation S103, the controller 220 may control impedance measurement of the plurality of batteries 10, 20, 30, and 40 by the plurality of measurement units 210 based on the voltages of the plurality of capacitors C being within the threshold range. In operation S103, for example, the controller 220 may determine whether the voltage of each of the plurality of capacitors C is within a threshold range of 1.8 V±5%.

In operation S103, when the voltage of each of the plurality of capacitors C is within the threshold range, the controller 220 may generate a control signal for measuring the impedances of the plurality of batteries 10, 20, 30, and 40 and transfer the control signal to the plurality of measurement unit 210.

In operation S103, each of the plurality of measurement units 210 may measure impedances of the plurality of batteries 10, 20, 30, and 40 based on a control signal of the controller 220. In operation S103, the plurality of measurement units 210 may measure impedances of the plurality of batteries 10, 20, 30, and 40 by using electrochemical impedance spectroscopy (EIS).

In operation S103, the plurality of measurement units 210 may calculate alternating current impedance spectrums of the plurality of batteries 10, 20, 30, and 40 based on a change in amplitude and phase of a signal detected from the plurality of batteries 10, 20, 30, and 40 with respect to a change in frequency of alternating current (AC) power applied to the plurality of batteries 10, 20, 30, and 40.

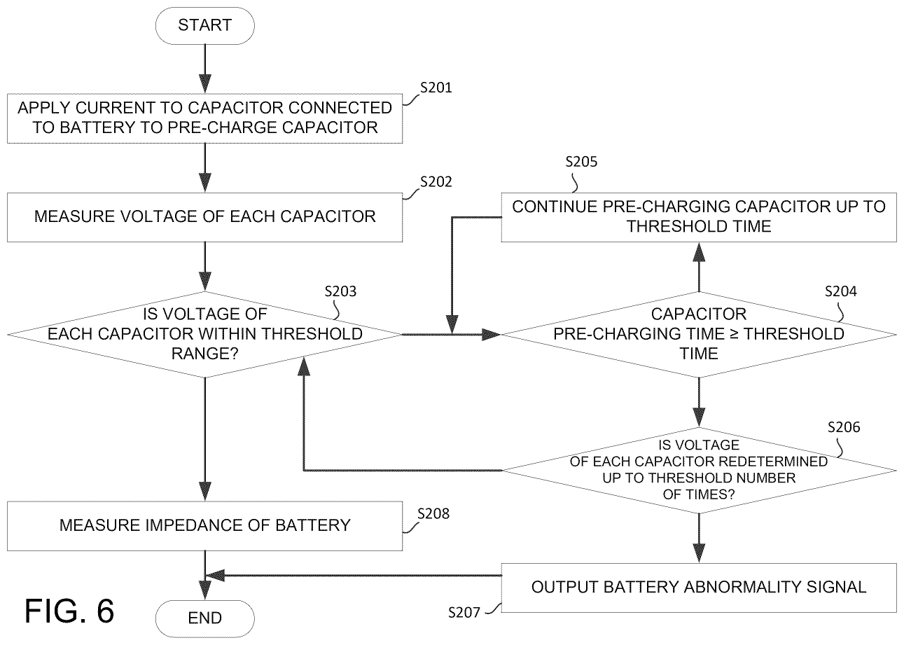

FIG. 6 is a flowchart showing an operating method of a battery management apparatus, according to another embodiment disclosed herein.

Referring to FIG. 6, an operating method of a battery management apparatus according to an embodiment disclosed herein includes operation S201 of applying current to a plurality of capacitors connected to a plurality of batteries to pre-charge the plurality of capacitors, operation S202 of measuring a voltage of each of the plurality of capacitors, operation S203 of determining whether the voltage of each of the plurality of capacitors is within a threshold range, operation S204 of determining whether a pre-charging time for the plurality of capacitors is within a threshold time, operation S205 of continue pre-charging the plurality of capacitors up to the threshold time, operation S206 of re-determining, up to a threshold number of times, whether the voltage of each of the plurality of capacitors is within a threshold range, operation S207 of outputting a battery abnormality signal, and operation S208 of measuring an impedance of the battery.

Hereinbelow, operations S201 through S208 will be described in detail with reference to FIGS. 1 and 4. The battery management apparatus 200 may be substantially the same as the battery management apparatus 200 described with reference to FIGS. 1 to 4, and thus will be briefly described to avoid redundant description.

In operation S201, each of a plurality of capacitors C may be electrically connected to opposite ends of at least one of the plurality of batteries 10, 20, 30, and 40.

In operation S201, the controller 220 may pre-charge the plurality of capacitors C by applying alternating current to the plurality of capacitors C.

In operation S202, the controller 220 may measure a voltage of each of the plurality of capacitors C. In operation S102, for example, the controller 220 may obtain a voltage of each of the plurality of capacitors C from an analog-to-digital converter (ADC) that converts a voltage of each of the plurality of capacitors C into a digital signal.

In operation S203, the controller 220 may determine whether the voltages of the plurality of capacitors C are within a threshold range. In operation S103, the controller 220 may control impedance measurement of the plurality of batteries 10, 20, 30, and 40 by the plurality of measurement units 210 based on the voltages of the plurality of capacitors C being within the threshold range. In operation S203, for example, the controller 220 may determine whether the voltage of each of the plurality of capacitors C is within a threshold range of 1.8 V±5%.

In operation S204, the controller 220 may determine whether the pre-charging time for pre-charging the plurality of capacitors C is greater than or equal to the threshold time, when the voltage of each of the plurality of capacitors C is out of the threshold range. In operation S204, for example, the controller 220 may determine whether the pre-charging time of the plurality of capacitors C is greater than or equal to a threshold time of 4000 ms, when the voltage of each of the plurality of capacitors C is out of a threshold range of 1.8 V±5%.

In operation S205, the controller 220 may continue pre-charging the plurality of capacitors C when the pre-charging time is less than the threshold time. In operation S205, for example, the controller 220 may continue pre-charging the capacitor C until the remaining time T_remain when the pre-charging time is less than the threshold time. Herein, the remaining time T_remain will be described with reference to [Equation 1] below.

$${T}_{remain} = α ( {V}_{max} - {V}_{adc} ) * ( \frac{{T}_{adc}}{{V}_{adc} - {V}_{init}} ) \qquad [ Equation 1 ]$$

Herein, a may mean an environment variable, i.e., a feature value of the capacitor C. V_max may be a maximum charging voltage of the capacitor C, e.g., 1.8 V. V_adc may mean a voltage of each capacitor C, obtained from an analog-to-digital converter. Herein, T_adc may mean a pre-charging time for pre-charging the plurality of capacitors C. V_init may mean the voltages of the plurality of capacitors C when pre-charging starts.

In operation S205, the controller 220 may calculate the remaining time T_remain based on [Equation 1], and continue pre-charging the plurality of capacitors C during the remaining time T_remain.

In operation S206, when the pre-charging time is greater than or equal to the threshold time, the controller 220 may re-determine whether the voltage of each of the plurality of capacitors C is within the threshold range after the elapse of a specific time. In operation S206, the controller 220 may redetermine, up to a threshold number of times, whether the voltages of the plurality of capacitors C are within the threshold range.

In operation S207, the controller 220 may generate abnormality signals of the plurality of batteries 10, 20, 30, and 40 when re-determining, up to the threshold number of times, whether the voltage of each capacitor C is within the threshold range. In operation S207, for example, the controller 220 may generate an error signal when redetermining whether the voltage of each of the plurality of capacitors C is within the threshold range three times that are the threshold number of times.

In operation S208, when the voltage of each of the plurality of capacitors C is within the threshold range, the controller 220 may generate a control signal for measuring the impedances of the plurality of batteries 10, 20, 30, and 40 and transfer the control signal to the plurality of measurement unit 210.

In operation S208, each of the plurality of measurement units 210 may measure impedances of the plurality of batteries 10, 20, 30, and 40 based on a control signal of the controller 220. In operation S208, the plurality of measurement units 210 may measure impedances of the plurality of batteries 10, 20, 30, and 40 by using electrochemical impedance spectroscopy (EIS).

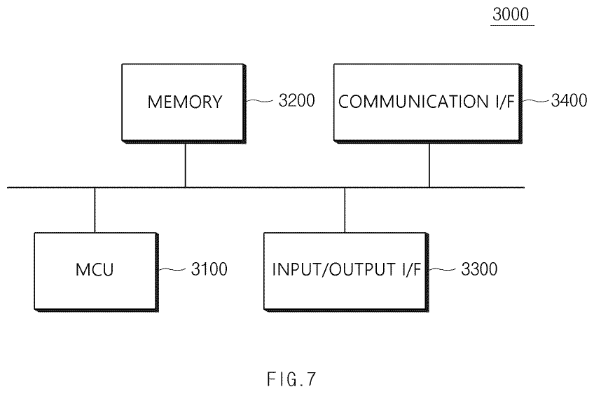

FIG. 7 is a block diagram showing a hardware configuration of a computing system for performing an operating method of a battery management apparatus, according to an embodiment disclosed herein.

Referring to FIG. 7, a computing system 3000 according to an embodiment disclosed herein may include an MCU 3100, a memory 3200, an input/output I/F 3300, and a communication I/F 3400.

The MCU 3100 may be a processor that executes various programs (e.g., a capacitor voltage calculation program) stored in the memory 3200, processes various data including an SOC, an SOH, etc., of a plurality of battery cells through these programs, executes functions of the battery management apparatus 200 described above with reference to FIG. 1, or executes the operating method of the battery management apparatus described with reference to FIG. 4.

The memory 3200 may store various programs related to impedance calculation of the plurality of batteries. Moreover, the memory 3200 may store various data such as SOC data, SOH data, etc., of each battery.

The memory 3200 may be provided in plural, depending on a need. The memory 3200 may be volatile memory or non-volatile memory. For the memory 3200 as the volatile memory, random access memory (RAM), dynamic RAM (DRAM), static RAM (SRAM), etc., may be used. For the memory 3200 as the nonvolatile memory, read only memory (ROM), programmable ROM (PROM), electrically alterable ROM (EAROM), erasable PROM (EPROM), electrically erasable PROM (EEPROM), flash memory, etc., may be used. The above-listed examples of the memory 220 are merely examples and are not limited thereto.

The input/output I/F 3300 may provide an interface for transmitting and receiving data by connecting an input device (not shown) such as a keyboard, a mouse, a touch panel, etc., and an output device such as a display (not shown), etc., to the MCU 3100.

The communication I/F 3300, which is a component capable of transmitting and receiving various data to and from a server, may be various devices capable of supporting wired or wireless communication. For example, a program for SOH calculation of the battery cell or target determination or various data, etc., may be transmitted and received to and from a separately provided external server through the communication I/F 3300.

As such, an operating method of a battery management apparatus according to an embodiment disclosed herein may be recorded in the memory 3200 and executed by the MCU 3100.

The above description is merely illustrative of the technical idea of the present disclosure, and various modifications and variations will be possible without departing from the essential characteristics of embodiments of the present disclosure by those of ordinary skill in the art to which the embodiments disclosed herein pertains.

Therefore, the embodiments disclosed herein are intended for description rather than limitation of the technical spirit of the embodiments disclosed herein and the scope of the technical spirit of the present disclosure is not limited by these embodiments disclosed herein. The protection scope of the technical spirit disclosed herein should be interpreted by the following claims, and all technical spirits within the same range should be understood to be included in the range of the present disclosure.

### EXPLANATION OF REFERENCE NUMERALS

10, 20, 30, 40: Plurality of Batteries
1000: Battery Swapping Station
100: Battery Slot Portion
200: Battery Management Apparatus
C: Capacitor
210: Measurement Unit
220: Controller
300: Charger
2000: Battery Pack
R: Relay
M1, M2, M3, M4: Battery Module
3000: Computing System
3100: MCU
3200: Memory
3300: Input/Output I/F
3400: Communication I/F

1. A battery management apparatus comprising:
one or more capacitors, each capacitor of the one or more capacitors connected to a respective battery among one or more batteries; and
a controller configured to apply current to each of the one or more capacitors to pre-charge the one or more capacitors, measure a respective voltage of each of the one or more capacitors, and, for each battery of the one or more batteries, control an impedance measurement of the battery based on whether the voltage of the capacitor connected to the battery is within a threshold range.

2. The battery management apparatus of claim 1, further comprising a sensor configured to measure impedance of the battery,
and
the controller is further configured to, in response to each capacitor being within the threshold range, generate a control signal for measuring the impedance of the battery connected to the capacitor and transmit the control signal to the sensor.

3. The battery management apparatus of claim 1, wherein the controller is further configured to, in response to the voltage of any capacitor being outside of the threshold range, determine whether a pre-charging time for pre-charging the capacitor is greater than or equal to a threshold time.

4. The battery management apparatus of claim 3, wherein the controller is further configured to re-determine whether the voltage of the capacitor is within the threshold range, in response to the pre-charging time for pre-charging the capacitor being greater than or equal to the threshold time.

5. The battery management apparatus of claim 4, wherein the controller is further configured to repeatedly determine whether the voltage of the capacitor is within the threshold range until either (i) the voltage of the capacitor is determined to be within the threshold range; or (ii) the voltage of the capacitor is determined to be outside of the threshold range a predetermined threshold number of times.

6. The battery management apparatus of claim 5, wherein the controller is further configured to generate an abnormality signal of the battery in response to the voltage of the capacitor being determined to be outside of the threshold range the predetermined threshold number of times.

7. The battery management apparatus of claim 4, wherein the controller is further configured to pre-charge the capacitor in response to the pre-charging time being less than the threshold time.

8. An operating method of a battery management apparatus, the operating method comprising:
applying current to a capacitor connected to a battery to pre-charge the capacitor;
measuring a voltage of the capacitor; and
measuring an impedance of the battery based on whether the voltage of the capacitor is within a threshold range.

9. The operating method of claim 8, wherein measuring the impedance of the battery comprises generating a control signal for measuring the impedance of the battery and transmitting the control signal to a sensor.

10. The operating method of claim 8, wherein measuring the impedance of the battery comprises determining, in response to the voltage of the capacitor being outside of the threshold range, whether the pre-charging time for pre-charging the capacitor is greater than or equal to the threshold time.

11. The operating method of claim 10, further comprising re-determining whether the voltage of the capacitor is within the threshold range in response to the pre-charging time for pre-charging the capacitor being greater than or equal to a threshold time.

12. The operating method of claim 11, further comprising repeatedly determining whether the voltage of the capacitor is within the threshold range until either (i) the voltage of the capacitor is determined to be within the threshold range; or (ii) the voltage of the capacitor is determined to be outside of the threshold range a predetermined threshold number of times.

13. The operating method of claim 12, further comprising generating an abnormality signal of the battery in response to the voltage of the capacitor being determined to be outside of the threshold range the predetermined threshold number of times.

14. The operating method of claim 11, further comprising generating a control signal for pre-charging the capacitor and transferring the control signal to the capacitor, in response to the pre-charging time being less than the threshold time.
